(19) United States
(12) Patent Application Publication
(10) Pub. No.: US 2021/0181265 A1
(43) Pub. Date: Jun. 17, 2021

(54) MONITORING SYSTEM FOR CABLE DRAG CHAINS

(71) Applicant: IGUS GMBH, Koeln (DE)

(72) Inventors: Thilo-Alexander JAEKER, Sankt Augustin (DE); Dominik BARTEN, Mechenheim (DE)

(21) Appl. No.: 16/971,546

(22) PCT Filed: Feb. 20, 2019
(86) PCT No.: PCT/EP2019/054247

§ 371 Date: Feb. 18, 2021

(30) Foreign Application Priority Data
Feb. 21, 2018 (DE) 20 2018 100 962.1

(51) Int. Cl. G01R 31/58; G01L 19/00; F16G 13/16; H02G 11/00

(52) U.S. Cl. CPC G01R 31/58; H02G 11/006; F16G 13/16; G01L 19/00

(57) ABSTRACT

The functional monitoring of a cable drag chain consisting of links or segments connected in an articulated manner for guiding one or more lines. The cable drag chain is equipped with a detection line for detecting a malfunction of the cable drag chain which is arranged at the level of the neutral fibre of the cable drag chain. According to the invention, the detection line is composed, at least over a part of the length of the cable drag chain, of a plurality of individual line sections which are conductively interconnected by detachable connections, such that a malfunction of the cable drag chain leads to the line-interrupting separation of at least one of the connections and the resulting line interruption can be detected by a detector. The invention further relates to a kit for retrofitting a cable drag chain having a detection line and to a monitoring system for an energy chain.

### FIELD

The invention relates in general to an energy guide chain for dynamically guiding one or more lines, such as cables, hoses or the like, between a base at one end of the energy guide chain and, at the other end of the energy guide chain, a moving end which is mobile relative to the base. The energy guide chain here has a plurality of links or segments which are connected to one another, wherein the links or segments are pivotable relative to one another to form a deflection arc. The invention furthermore relates to a kit for retrofitting an energy guide chain for the purpose of monitoring and to an energy guide chain monitoring system.

### BACKGROUND

While an energy guide chain is in operation, faults in its operating state may occur, possibly resulting in a malfunction of the energy guide chain. An energy guide chain may be damaged by external influences, for example by objects which may get into the travel path of the energy guide chain and prevent proper travel of the chain. If, in the event of such a fault, the moving end pushes the links of the chain in front of it under pressure, the links or segments may pivot contrary to the desired link pivoting direction which is provided for formation of the deflection arc. In particular in the portion of the chain adjoining the moving end, this may result in the formation of an arc which deviates from the proper travel path or even in partial or complete breakage of the chain. External influences or chain wear may furthermore cause damage such as chain link or segment breakage. Continuing to operate the energy guide chain after such a fault may result in the guided lines being damaged or even snapping. Early identification of a malfunction of the energy guide chain means that chain operation can be stopped and the fault eliminated. In the event of a chain link or segment breaking, the damaged parts may be replaced or repaired.

A malfunction of the energy guide chain must accordingly be identified as quickly as possible in order to avoid damage to the guided lines or even the machinery supplying them.

On the one hand, various approaches have already been proposed for identifying a break in an energy guide chain:

EP 1 521 015 A2 proposes a breaking element in the form of an electrical line which is mounted along an outer side of the energy guide chain and is fixed to joint pins of the links. In the event of the chain breaking, the detection line also breaks, which causes the chain to stop. When the chain is repaired, the electrical line also has to be replaced and laboriously drawn back in over the entire length of the chain.

JP 2009-052714 A proposes a system for detecting a chain break in which an optical cable is fastened along an outer side of an energy guide chain and the light which is conducted by the cable is measured by a detector. In the event of a break in one of the chain links, the system functions similarly to the above-stated system and requires laborious repair.

WO 2015/118143 A1, in contrast, proposes an energy guide chain with a flexible triggering cord which has limited extensibility as a detection line which is guided at the neutral axis height of the energy guide chain. The triggering cord cooperates with a mechanical detector for detecting a break in the chain. In the event of a break in the chain, the position of a transducer changes in the longitudinal direction of the chain and this is identified by the detector. Replacement of the triggering cord is not generally necessary after a break.

On the other hand, solutions are also already known for specifically identifying an unintended course of an energy guide chain, in which a chain break has not (yet) occurred:

DE 20 2004 005 858 U1 for example describes a solution in which chain links are in each case provided with a registration device which is capable of detecting any swiveling of a chain link which goes beyond a normal angular range. The registration device has switching means which, in the event of the chain link swiveling out of its normal arrangement beyond the predetermined angular range, switches over from a first switch state into a second switch state and this is detected by the registration device. This solution has indeed proven effective, but is really complex.

### SUMMARY

The problem addressed by the present invention is that of proposing a simple yet robust solution. The solution should additionally optionally be suitable for detecting a break in an energy guide chain or for detecting an unintended course or also for detecting both of the above-stated types of energy guide chain malfunction.

A generic energy guide chain comprises a plurality of links or segments which are connected to one another for guiding one or more lines, such as cables, hoses or the like, between a base at one end of the energy guide chain and, at the other end of the energy guide chain, a moving end which is mobile relative to the base, wherein the links or segments are pivotable relative to one another to form a deflection arc. The generic energy guide chain is here equipped with a detection line which is provided in dedicated or intended manner for identifying a malfunction of the energy guide chain and is arranged substantially at the neutral axis height of the energy guide chain.

According to the invention, the detection line is composed of a plurality of individual longitudinal line portions which are conductively connected to one another by disconnectable connections, such that a malfunction of the energy guide chain leads to at least one of the connections being undone in conduction-interrupting manner and the resultant interruption in conduction is detectable with a detector. The detection line thus consists, with regard to the longitudinal direction thereof, of a number of individual line portions. It need not be provided over the entire length of the energy guide chain but should instead be present at least over a significant part of the length of the energy guide chain. It may in particular be provided over a length corresponding to the movement range of the deflection arc.

The detection line is a dedicated line provided in separate or intended manner for monitoring, i.e. is intended for detecting a malfunction of the energy guide chain. The detection line thus does not correspond to one of the lines which are dynamically guided by the energy guide chain as supply lines for the desired application. The detection line thus need not be led out at the end for example of the energy guide chain. The detection line may, however, comprise components which can also perform further functions in the energy guide chain, for example separating webs.

Over a length corresponding to the range over which the deflection arc moves as a result of movement of the moving end, the detection line may thus be composed of individual line portions which are disconnectably connected to one another in order to form over this range a multipart line which is, however, continuously conductive in respect of the detection medium used. The detection line may here for example conduct a detection medium or signal when the detection line is intact. A detector may be connected to the detection line in order to monitor the detection medium or the signal and for example detect a change relative to the nominal state when the detection line is intact.

Failure of the energy guide chain may in particular lead to at least one of the disconnectable connections between two successive line portions being undone, i.e. to a loss of detection line integrity. This inherently results in a measurable change in state or signal which is measurable on the detection line. The individual connections may thus, as intended, act like disconnectable, in particular non-destructively disconnectable, predetermined breaking points.

One advantage of the solution according to the invention is that the detection line can also be quickly repaired in the event of a malfunction or indeed of a false alarm. The integrity of the detection line can be restored quickly without replacement by restoring the connection which has previously become undone. Moreover, in comparison with permanently laid continuous lines, it is also possible to repair the energy guide chain more simply, for example by replacing parts of the energy guide chain, for example a chain link, if the detection line can be undone and restored as required. Continuous detection lines mounted on the chain links might, depending on their design, sometimes considerably complicate repair.

With regard to terminology, a deflection arc here means a region of an energy guide chain in which the course or direction of movement of the links or segments changes, for example reverses by approximately 180°. Adjacent links or segments in the region of the deflection arc are pivoted relative to one another in a desired “forward direction”, i.e. the longitudinal axes thereof (parallel to the longitudinal direction of the chain) intersect at an angle which is less than 180°. On travel of the energy guide chain, the deflection arc travels along with it, i.e. different links or segments in each case form the deflection arc. The term links relates to a true link chain of individual links. The invention is generally applicable to active line guides, for example those with flexible strips which are continuous in places or throughout, with which segments for guiding the line are pivotably connected or manufactured in one piece. The neutral axis, also denoted neutral line, corresponds to the layer of the cross-section of the energy guide chain, the length of which undergoes no change during pivoting or travel of the deflection arc. Deflection exposes the lines guided in this cross-sectional position to the least tensile/thrust load.

The disconnectable connections which connect the line portions to one another may be embodied as plug-in connections and this applies to all, or at least the majority, of the disconnectable connections. The detection line may thus simply be composed of individual line portions. Even after an interruption in conduction of the detection line in the event of a malfunction of the energy guide chain, the integrity of the detection line can be straightforwardly and quickly restored by plugging the line portions together.

The plug-in connections may in particular be embodied as plug-in connections which can be plugged together in the longitudinal direction of the line. The longitudinal direction of the detection line corresponds to the longitudinal direction of the other or guided lines which the energy guide chain guides from a base to a moving end or to the direction of the course of the energy guide chain. In one embodiment at least one connector may be provided for each disconnectable connection between two successive line portions. The connector(s) may preferably be held on a link or segment by a holder in order to specify a nominal position in the longitudinal direction. The holder may here also position the connector at neutral axis height. Reliable positioning of the detection line at neutral axis height is advantageous here. Various designs of holder are possible.

The detection line should be provided over part of the length of the energy guide chain, at least over the first third of the length of the energy guide chain closest to the moving end.

A disconnectable connection for conductively connecting two line portions should be mechanically held, preferably at neutral axis height, on every second link or segment, preferably on each link or segment, at least over a part of the length which is critical with regard to malfunction. The connection between in each case two successive line portions may to a certain extent be mobile or also be fixed in the longitudinal direction of the energy guide chain.

In one embodiment, the holder may lock or fix the connector to the link or segment in the longitudinal direction of the energy guide chain, i.e. the connector may be held on the link or segment in such a manner that no appreciable displacement of the connector in the longitudinal direction relative to the link or segment of the energy guide chain is possible without the connection between two successive line portions being undone. The connector may here be fixedly held, in particular fastened, or disconnectably held on the link/segment. It is advantageous here that a malfunction of the chain between in each case two links or segments of the energy guide chain, to which one line portion is locked at the end by two connectors, will lead to separation of at least one of the two connections and is thus detectable.

In one particularly preferred embodiment, each line portion of the detection line may be embodied as a pressure hose portion for a pressure medium, in particular as a pneumatic pressure hose portion for compressed air. Each connector may here be embodied as a pneumatic coupling piece which has a duct for the pressure medium and is equipped on both sides in the longitudinal direction of the energy guide chain with two hose nozzles, each of which (in the manner of a compressed air hose nozzle or port) permits a disconnectable plug-in connection with a pressure hose portion such that each of the coupling pieces can conductively connect two pressure hose portions. It is particularly advantageous in this embodiment that conventional commercial pressure hoses, for example of standard NW 7.2 mm design, constitute an inexpensive variant for a detection line. In addition, compressed air is not generally a source of interference for the guided lines.

Each pressure hose portion may thus preferably be embodied as a pneumatic pressure hose portion and each coupling piece may be held at neutral axis height by a holder, in particular in the form of a separating web. The coupling piece, for example with its hose nozzles, may be embodied, in particular in one piece, with the separating web or take the form of part of the separating web. This embodiment is an advantageous variant in which the detection line can be simply retrofitted and particularly simply repaired even after separation of one of the connections of the line portions. Another conceivable embodiment is one in which a pressure hose portion is in each case fixedly connected to a separating web or forms an assembly, wherein the conductive connections between such assemblies are embodied as plug-in connections of in each case two pressure hose portions.

In one alternative embodiment of the energy guide chain, each line portion of the detection line may comprise an electrical conductor and the connections may in each case be embodied by suitable electrical plug-in connectors, in particular by pairs of conjugate plug-in connectors. Plug-in connectors disconnectable at a predefined force are commercially available and inexpensively obtainable not only for pneumatic line systems, but also for electrical lines.

Adjacent line portions preferably each have approximately the same conductivity. Identical conductivity may for example reduce troublesome reflection of the detection medium.

Alternatively, but less preferably, each line portion could comprise an optical guide and the connections may in each case be embodied by two optical plug-in connectors.

Each plug-in connector may be held in place at neutral axis height by a holder, in particular in the form of a separating web. The holder may for this purpose have a socket which is embodied to fit the plug-in connector such that each of the holders can in each case hold a conductive connection of two line portions at a predetermined location in the longitudinal direction. The sockets may be embodied such that the plug-in connectors are locked in the sockets in the longitudinal direction of the energy guide chain. It is advantageous for a malfunction of the chain between in each case two sockets to be capable of leading to the separation of the intentionally disconnectable connection of the two line portions.

The tensile strength of the disconnectable connection between two line portions is preferably lower than the tensile strength of these line portions.

Should the detection line be exposed to tensile stress in the event of a malfunction of the energy guide chain and one or more of the connections be disconnected as a result, the line portions themselves would remain undamaged thereby, i.e. they can be reconnected in order to restore the detection line.

The disconnectable connections are preferably non-destructively disconnectable, in particular disconnectable without destroying one of the line portions they connect, such that the integrity of the detection line can be quickly restored without replacement of the line portions.

The connections are preferably disconnectable at a predefined force. This force may be appropriately selected for example on the basis of the type of guided lines the energy guide chain is to guide and depending on the construction of the chain such that these disconnectable connections are not undone during normal operation, but are undone in the event of a malfunction of the energy guide chain. Accordingly, it is possible if required to provide a robust detection line which can remain intact in the event of relatively low levels of stress.

In one embodiment, at least some of the holders may each have a lever projection protruding in the longitudinal direction of the energy guide chain, which projection is embodied and arranged such that, in the event of undesired pivoting of the links or segments of the energy guide chain contrary to the proper pivoting direction, the lever projection can interact with the adjacent line portion in order to undo the connection thereof to the next line portion. The proper pivoting direction is the direction desired for forming the deflection arc. This embodiment is particularly advantageous for identifying an unintended course of the energy guide chain. In the event of overbending of the energy guide chain, i.e. excessive pivoting of the links or segments contrary to the proper pivoting direction, the lever projection may come into contact with the associated line portion and act on the latter in such a way that its connection to the next line portion is undone.

At least some line portions of the detection line, preferably each line portion, may be disconnectably fastened at the end to one of two adjacent links or segments of the energy guide chain. As a result, in the event of a malfunction of the energy guide chain, the fastening can disconnect itself, optionally even without additional aids, such as for example lever projections. In one embodiment, two successive line portions may in each case be disconnectably fastened to each link or segment of the energy guide chain with one of their two ends, in particular by the component serving as a connector being held or integrated there. The two line portions may be disconnectably fastened with their respectively other end to an adjacent link or segment of the energy guide chain.

In one embodiment, the detection line may form a loop along at least one part of the length of the energy guide chain, starting from one end of the energy guide chain and returning to said end. This embodiment offers the design advantage that detection line connection points, for example for a source and for the detector may be arranged at one and the same end of the energy guide chain, so simplifying the design.

The energy guide chain may comprise links or segments with an accommodation space for accommodating the guided lines which is in each case bounded by at least one side plate, typically by two opposing parallel side plates, wherein the side plates are swivelably connected to one another in the longitudinal direction of the energy guide chain and form at least one string of plates. The detection line, in particular the loop thereof, may be arranged in the accommodation space, preferably laterally externally to the accommodation space, on the string of plates. The detection line may be arranged as a loop on a string of plates. The detection line may be arranged on the inside of the string of plates, namely on the side facing toward the accommodation space of the links or segments of the energy guide chain. Alternatively, the detection line may also be arranged on the outside of the string of plates.

In one widely used embodiment, the side plates may be swivelably connected to one another for example by conventional socket-and-pin connection in the longitudinal direction of the energy guide chain. However, other articulated connections, for example using flexible articulated elements, also fall within the scope of the invention.

The invention further relates to a kit for retrofitting an energy guide chain having an intended detection line for detecting a malfunction of the energy guide chain and comprising
a plurality of individual line portions which are conductively connectable to one another by disconnectable connections to form a detection line;
connectors for creating the disconnectable connections between the line portions; and
holders for arranging the detection line at the neutral axis height of the energy guide chain over at least part of the length of the energy guide chain, in particular over a length corresponding to the movement range of the deflection arc.

In the context of the invention, a malfunction of the energy guide chain results in at least one of the connections being undone in conduction-interrupting manner such that the resultant interruption in conduction may be detected with a detector. In particular, separating webs may be used as holders. Separating webs are typically embodied such that they can be suitably mounted on links or segments of the energy guide chain, i.e. it is easy to retrofit the energy guide chain with such separating webs.

The invention further relates to an energy guide chain monitoring system comprising
a detection line which is composed of a plurality of individual line portions which are conductively connected to one another by disconnectable connections in order, in the event of a malfunction of the energy guide chain, to render, as the result of at least one these connections being undone in conduction-interrupting manner similarly to a “predetermined breaking point”, the resultant interruption in conduction detectable with a detector;
a number of holders for arranging the detection line, in particular at the neutral axis height and over at least part of the length of the energy guide chain, in particular over a length corresponding to the movement range of the deflection arc;
at least one source of a detection medium, wherein the source is conductively connected with the detection line in order to feed the detection medium into the detection line;
a detector which is connected to the detection line in order to detect an intended nominal interruption to the detection line in the event of malfunction; and
an evaluation unit with which the detector is connected in a signal-transmitting manner

In one preferred embodiment, the source may feed compressed air into the detection line and the detector may be embodied as a pressure sensor. The presence of a predetermined nominal pressure in the detection line may serve as a signal for the detector as to the integrity of the detection line. Alternatively, the source may for example provide electrical voltage for the detection line and the detector may be embodied to measure an electrical voltage. The magnitude of the electrical voltage on the detection line may serve as a signal for the detector as to the integrity of the detection line. The presence of the optical signal which is transmitted by the detection line to the detector may serve as a signal for the detector as to the integrity of the detection line.

The evaluation unit may be embodied to detect a malfunction of the energy guide chain when the detector detects an interruption of the detection line, for example to trigger an emergency stop of the moving end of the energy guide chain or other protective measures. The evaluation unit may be embodied to send a signal for stopping the moving end to a machine or system controller. A suitably programmable evaluation unit is for example offered for sale by the applicant under the tradename “Evaluation Unit PPDS.EU.01.SMD”.

The holders may be embodied as separate components, in particular as separating webs, which are connectable to the links or segments of the energy guide chain. This embodiment is advantageous for retrofitting an energy guide chain with a detection line. Alternatively, suitable holders may for example be embodied in one piece with other components of the energy guide chain or be subsequently mounted in another way on the energy guide chain, for example on the side plates.

The disconnectable connections which connect the individual line portions to one another are preferably embodied as plug-in connections. As a result, the connections may for example in particular only be disconnected on exposure to a predefined force and/or easily restored.

### BRIEF DESCRIPTION OF THE DRAWINGS

Further details, advantages and features of the invention may, without limitation, be inferred from the following part of the description in which exemplary embodiments of the invention are explained in greater detail with reference to the appended drawings. Components with an equivalent function or structure are provided with corresponding reference signs. In the figures:

FIG. 1a shows a first exemplary embodiment of an energy guide chain with a pneumatic detection line, shown in longitudinal section;

FIG. 1b shows a magnified portion of FIG. 1a (region N);

FIG. 1c shows a perspective view of a separating web of the energy guide chain according to FIG. 1a;

FIG. 1d shows a front view of the separating web according to FIG. 1c;

FIG. 2a shows a second exemplary embodiment of an energy guide chain with a pneumatic detection line, shown in longitudinal section;

FIG. 2b shows a magnified portion of FIG. 2a (region R);

FIG. 2c shows a magnified portion of FIG. 2a (region M);

FIG. 2d shows a perspective view of a separating web of the energy guide chain according to FIG. 2a;

FIG. 3a shows a further exemplary embodiment of an energy guide chain, in this case with an electrical detection line, shown in longitudinal section;

FIG. 3b shows a magnified portion of FIG. 3a (region E);

FIG. 3c shows a perspective view of a separating web of the energy guide chain according to FIG. 3a;

FIG. 3d shows a front view of the separating web according to FIG. 3c;

FIG. 3e shows a cross-section of the separating web according to section plane E-E in FIG. 3d;

FIG. 4 shows a further exemplary embodiment of an energy guide chain with a pneumatic detection line, in this case in perspective view; and

FIG. 5 shows a schematic representation of a monitoring system according to the invention.

### DETAILED DESCRIPTION

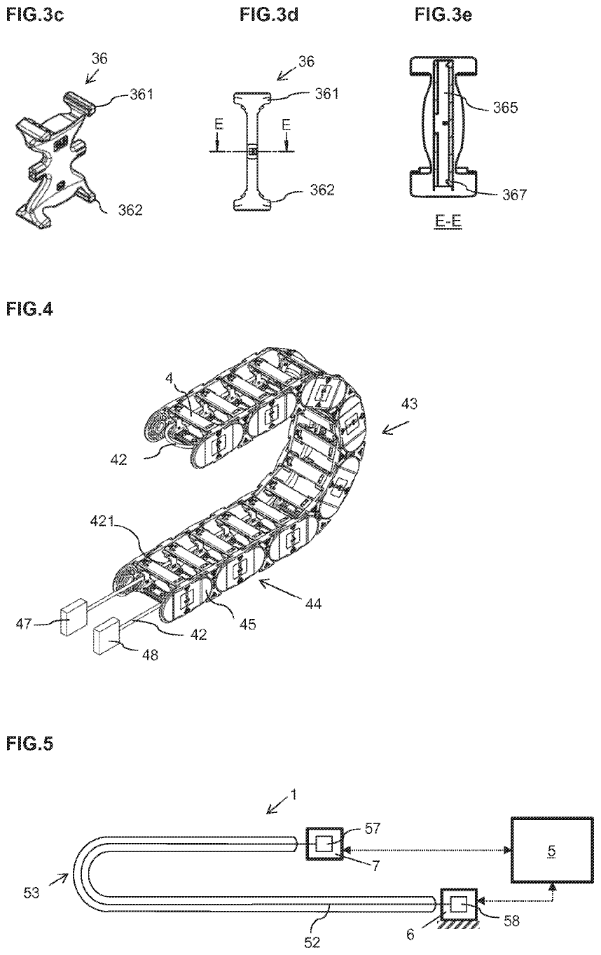

FIG. 5 shows by way of example a schematic diagram of a monitoring system which monitors an energy guide chain 1 for malfunction. The energy guide chain 1 guides and protects lines from a usually stationary base 6 to a moving end 7 which moves, for example linearly back and forth, relative to the base 6. The energy guide chain 1 typically forms a deflection arc 3 with a predetermined radius and has a predetermined nominal course, for example with a straight lower run 2, an extended pretensioned, slightly sagging or slumping upper run 4 and the predetermined deflection arc 3 moving back and forth therebetween.

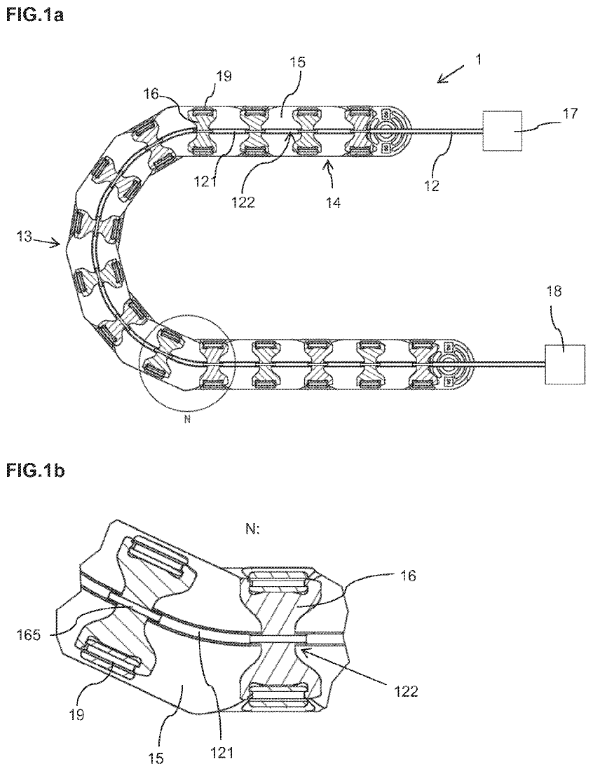

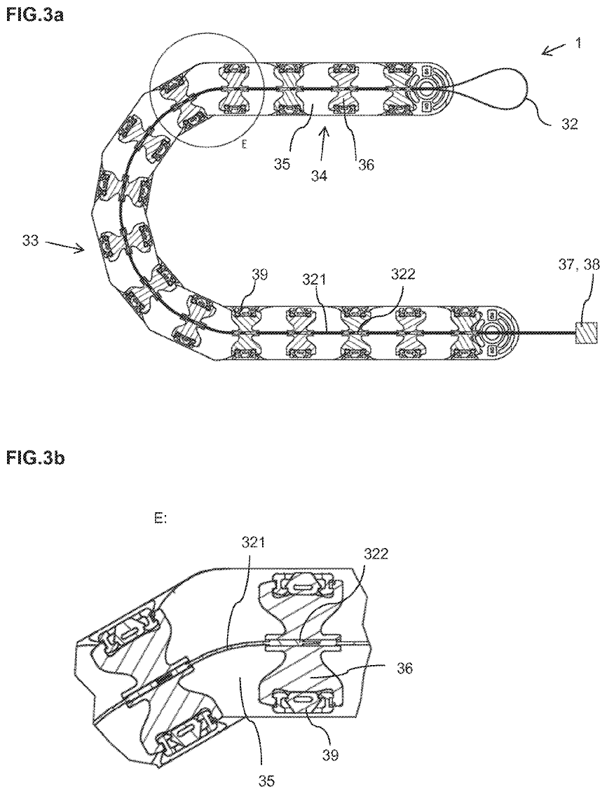

As shown in FIGS. 1a-1d, an energy guide chain 1 is for example made up of a plurality links 14 which are concatenated in the longitudinal direction and are pivotable relative to one another. The links 14 have limit stops for maintaining the deflection arc 13 with a predefined radius. Each link 14 comprises two side plates 15, only one of which is shown in FIG. 1a. The two side plates 15 of a link 14 are spaced from one another in the transverse direction, i.e. perpendicular to the longitudinal direction of the energy guide chain 1 or the plane in FIG. 1a, and are connected to one another by two transverse webs 19 (cf. transverse webs 49 in FIG. 4). Concatenation of the side plates 15 in each case forms one of two strings of plates which are correspondingly connected to one another and held parallel by the transverse webs 19 (cf. FIG. 4). The side plates 15 and the transverse webs 19 form therebetween an accommodation space in which guided lines (not shown) are accommodated in the respective link 14. Adjacent plates 15 in each string of plates overlap in the longitudinal direction of the chain 1 and are pivotable relative to one another. FIG. la shows a design of a link chain with internal and external plates in which each link 14 is made up of four individual parts. The invention is, however, suitable for any design of active line guides.

As FIGS. 1a-1d further show, the energy guide chain 1 is equipped with a dedicated special line, namely a detection line 12. According to the invention, the detection line 12 consists of a plurality of line portions 121 which are serially connected to one another in the longitudinal direction. In the first exemplary embodiment, the detection line 12 is embodied as a pneumatic pressure hose which is composed of pressure hose portions 121. All the pressure hose portions 121 are identical, in particular with regard to length and predetermined nominal diameter. When using compressed air as detection medium, the detection line 12 is for example intended to maintain a specific pressure losslessly. Pairs of successive pressure hose portions 121 are disconnectably and conductively connected to one another by suitable connectors. Each connector in FIGS. 1a-1d is embodied as a coupling piece 122 or in the manner of a hose connector or hose nozzle to ensure a sufficiently pressure-resistant connection of two pressure hose portions 121. As shown in greater detail in FIG. lb, each coupling piece 122 is here embodied as an integral component of a special separating web 16 and produced in one piece therewith, for example from plastics by injection molding.

As is apparent in greater detail from FIG. lc, each separating web 16 may in known manner be fastened on both sides to a transverse web 19, for example in form-fitting and force-locked manner using fastening clips 161, 162. A separating web 16 here extends transversely of the transverse webs 19 and of the longitudinal direction of the chain 1 and (sub)divides the accommodation space of a link 14. Each separating web 16 forms two axially opposing hose nozzles 163, 164 as key components of the respective connector 122. The hose nozzles 163, 164 are positioned centrally on the separating web 16 such that, when the separating web 16 is installed in the energy guide chain 1, the hose nozzles 163, 164, and thus also the connector 122, are overall located at the neutral axis height of the chain 1. Each hose nozzle 163, 164 is appropriately dimensioned to form a disconnectable plug-in connection with a respective pressure hose portion 121. In particular, the diameters of the hose nozzles 163, 164 are coordinated with the diameter of the pressure hose portions 121 in such a manner that the pressure hose portions 121 can be manually pushed onto the hose nozzles 163, 164, so ensuring a conductive, in this case pressure-tight, connection. The dimensions of the hose nozzles 163, 164 and the length of the pressure hose portion 121 are moreover selected such that the connection is disconnected on exposure to unintended load, for example under slight tensile force by excessive bending of the pressure hose portion 121. As a result, the connection of the respective hose nozzle(s) 163, 164 with the pressure hose portion 121 may be disconnected automatically at a critical point should an undesired malfunction of the energy guide chain 1 occur, such as for example a break in the string of plates or the upper run 4 rearing up. It is alternatively also possible not to push the pressure hose portions 121 onto the hose nozzles 163, 164 but instead to insert them therein.

The two hose nozzles 163, 164 of a separating web 16 are connected by a duct for compressed air 165 in the separating web 16 which forms a further component of the connector 122 in FIGS. 1a-1d. In this embodiment, the detection line 12 thus consists of pressure hose portions 121, hose nozzles 163, 164 and ducts 165 in separating webs 16. Due to the design of the separating webs 16, the detection line is located at the neutral axis height of the energy guide chain 1 and is held in a direction transverse to the longitudinal direction of the chain 1. In this case, the separating webs 16 thus firstly function as holders which hold the detection line 12 at neutral axis height and secondly function as connectors 122 which disconnectably connect the line portions 121. As shown in FIG. lc, the separating web 16 is embodied as a flat body, the thickness of which in the central region is, however, sufficient to accommodate the diameter of the duct 165.

The separating webs 16 thus hold each pressure hose portion 121 in place at its ends on two adjacent links 14 in the longitudinal direction of the energy guide chain 1. A break in a link 14, for example a break in a side plate 15, will change the distance between separating webs 16 located on each side of the breaking point. Such a change in distance will lead to at least one of the two connections between the pressure hose portion 121 directly by the breaking point and one of the two adjoining separating webs 16 being undone or disconnected. An at least transient pressure drop occurs, this being easily measurable at one end of the detector line 12. The energy guide chain 1 is to this end equipped with a compressed air source 17 and a detector 18 which is embodied as a pressure sensor. The detector 18 and compressed air source 17 are connected to the opposite ends of the detector line 12. The compressed air source 17 serves as a buffer and ensures that a specified pressure is maintained in the detection line 12 over the long term. The pressure sensor 18 can establish whether the pressure in the detection line 12 has fallen in the short term as a result of the detection line 12 being undone in conduction-interrupting manner For automation purposes, the pressure sensor 18 is connected for data transfer to an evaluation unit 50 which is in turn connected for data transfer, for example, to the controller of the moving end 7, for example wirelessly by radio. The evaluation unit 50 may in particular trigger an emergency stop of the moving end 7 of the energy guide chain 1 such that the chain 1 can be repaired after a break before more serious damage, in particular to the guided lines, occurs.

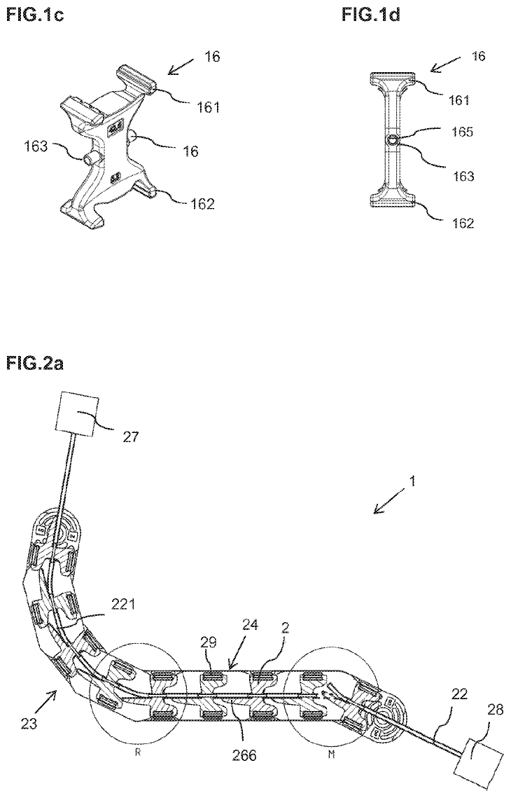

FIGS. 2a-2c show a second exemplary embodiment of the monitoring device according to the invention for an energy guide chain 1. Said device also makes it possible reliably to detect an unintended course of the energy guide chain 1, in particular undesired pivoting of the links 24 (contrary to the pivoting direction of the deflection arc 23).

The variant in FIG. 2a primarily differs from that in FIG. 1a by the separating webs 26 having an additional function. In this embodiment, the separating webs 26 additionally have a lever projection 266 which protrudes in the longitudinal direction of the energy guide chain 1. When, as a result of a fault, adjacent links 24 pivot toward one another beyond the predetermined angular range in a direction which does not correspond to the nominal or forward pivoting direction of the links 24 in the deflection arc 23, the lever projection 266 comes into contact with the adjacent line portion 221 and, by lever action, undoes the connection of the corresponding line portion 221 to the connector 222 on the adjacent separating web 26. The integrity of the detection line 22 is also interrupted as a consequence and this can be detected by the detector 28. The pivoting direction of the adjacent links 24 shown in greater detail in FIG. 2b corresponds to the desired pivoting direction for forming the deflection arc 23, and the lever projection 266 does not obstruct said pivoting direction. In FIG. 2c, in contrast, the pivoting direction of the adjacent links 24 does not correspond to the desired pivoting direction. The lever projection 266 then acts on the line portion 221 in order to undo the connection of the line portion 221 to the connector 222 on the adjacent separating web 26. FIG. 2d shows the separating web 26 as an individual part which, as in FIG. 1c, has per se known fastening clips 261, 262 for the transverse web 29 and, according to the invention, a connector 222 with hose nozzles 263, 264 and a compressed air duct 265.

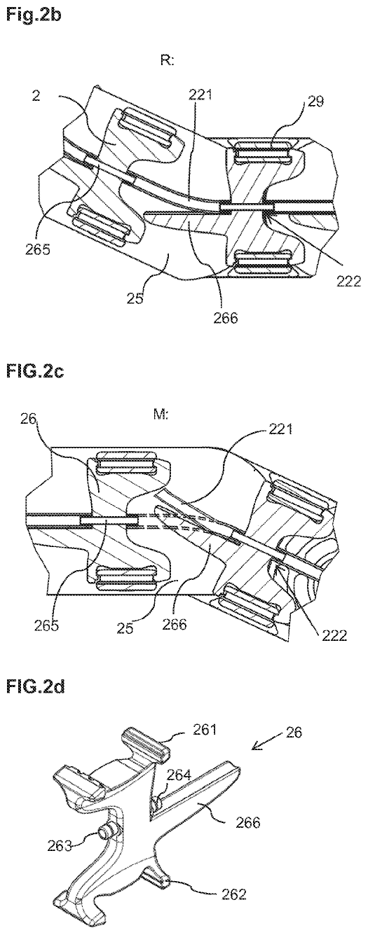

FIG. 3a shows an alternative exemplary embodiment of the detection line 32 according to the invention which functions by an electrical principle of operation. The energy guide chain 1 is similar in structure to FIG. la with the exception of the design of the detection line 32 and the separating webs serving as holders for the detection line 32. In the embodiment shown in FIG. 3a, the detection line 32 comprises a plurality of line portions 321 which comprise electrical conductors. The electrical line portions 321 are conductively connected to one another by electrical plug-in connectors 322 in order to permit a disconnectable current-conducting connection of two line portions 321. Current or voltage may thus be used in this case as the detection medium or signal. It is in principle also possible to use an optical principle of operation with light guides.

FIG. 3b shows the disconnectable plug-in connection in greater detail. Each electrical plug-in connector 322 is held on a separating web 36 at neutral axis height. The separating web 36 forms to this end a socket 365 which is embodied to fit the two interacting (male/female) connector parts of the plug-in connector 322. Each of the separating webs 36 here therefore serves, without contributing to the actual connection function, as a holder for the plug-in connector 322 and thus also for positioning the two adjacent line portions 321. When the separating webs 36 are installed, the sockets 365 for the plug-in connectors 322 are likewise located at neutral axis height such that the separating webs 36 position and hold the detection line 32 at neutral axis height. The plug-in connectors 322 may be disconnectably locked in the sockets 365 in the longitudinal direction of the energy guide chain such that a malfunction of the chain 1 between in each case two sockets 365 leads to the connection of the two line portions 321 being undone in conduction-interrupting manner FIG. 3e shows a section plane E-E of the separating web 36 along the neutral axis in which a locking device 367 is visible in the socket 365. A variant in which the separating webs 36 are as in FIGS. 2a-d is also possible.

The detection line 32 shown in FIG. 3a is connected at the end with a current or voltage source 37 and with a detector 38 which can detect electrical voltage. The detector 38 can for example establish when the voltage in the detection line 32 changes abruptly, as is intended to occur as a result of the detection line 32 being undone in conduction-interrupting manner The detector 38 is connected for signaling to an evaluation unit 50 which is in turn connected to the controller of the moving end 7.

The electrical detection line 32 shown in FIG. 3a may be more easily laid as a loop, i.e. starting from one end of the energy guide chain 1 and returning to said end. A loop need not here extend over the entire energy guide chain 1. Each plug-in connector 32 is embodied as a connector for a pair of two electrical conductors. In FIG. 3a, the source 37 and the detector 38 are arranged as a functional unit at the same end of the energy guide chain 1.

FIG. 4 shows an exemplary embodiment of the energy guide chain 1 in which the detection line 42 is embodied as a compressed air line which forms a loop along the energy guide chain 1. The compressed air source 47 and the detector 48 are both arranged at one and the same end of the energy guide chain 1. The detection line 42 in FIG. 4 adjoins the inner sides of the plate strings, laterally externally in the accommodation space of the energy guide chain 1 so as to be able more readily to detect a break in each string of plates. The detection line 42 extends along a string of plates starting from the source 47 at the base 6 of the chain 1 to the other end of the chain 1 and back along the other string of plates. The holders for the detection line 42 are arranged on the side plates 45 such that more space for lines such as hoses and cables remains in the central region of the cross-section of the energy guide chain 1.

As mentioned above, FIG. 5 shows a general schematic diagram of the monitoring system according to the invention for an energy guide chain 1. The monitoring system comprises a detection line 52 which is held by holders at neutral axis height, a source 57 which can feed a detection medium into the detection line 52 and a detector 58 which monitors the detection medium in the detection line 52 with regard to a change of state. An evaluation unit 50 is connected for data transfer to the detector 58 in order to trigger measures for protecting the energy guide chain 1 and the lines guided therein if undesired behavior is indicated by the detection line 52.

### LIST OF REFERENCE SIGNS

FIG. 1

12 Detection line

121 Line portion

122 Coupling piece

13 Deflection arc

14 Energy guide chain link

15 Side plate

16 Separating web

161; 162 Fastening clips

163; 164 Hose nozzles

165 Duct in the separating web

17 Source

18 Detector

19 Transverse web

FIG. 2

22 Detection line

221 Line portion

222 Coupling piece

23 Deflection arc

24 Energy guide chain link

25 Side plate

26 Separating web

261; 262 Fastening clips

263 Hose nozzles

265 Duct in the separating web

266 Lever projection

27 Source

28 Detector

29 Transverse web

FIG. 3

32 Detection line

321 Line portion

322 Plug-in connector

33 Deflection arc

34 Energy guide chain link

35 Side plate

36 Separating web

361; 362 Fastening clips

365 Socket in the separating web

367 Locking device

37 Source

38 Detector

39 Transverse web

FIG. 4

42 Detection line

421 Line portion

43; Deflection arc

44 Energy guide chain link

45 Side plate

47 Source

48 Detector

49 Transverse web

FIG. 5

1 Energy guide chain

2 Lower run

3 Deflection arc

4 Upper run

6 Base (fixed point)

7 Moving end

50 Evaluation unit

What is claimed is:

1-22. (canceled)

23. An energy guide chain, comprising:
a plurality of links or segments which are connected to one another to guide one or more lines between a base at one end of the energy guide chain and a moving end, which is mobile relative to the base, at another end of the energy supply chain;
wherein the links or segments are pivotable relative to one another to form a deflection arc;
wherein the energy guide chain is equipped with a detection line to detect a malfunction of the energy guide chain;
wherein the detection line is arranged at a neutral axis height of the energy guide chain; and
wherein the detection line comprises, along at least a part of a length of the energy guide chain, a plurality of individual line portions which are conductively connected to one another by disconnectable connections, the detection line operable such that a malfunction of the energy guide chain leads to at least one of the disconnectable connections being undone in conduction-interrupting manner and a resultant interruption in conduction is detectable with a detector.

24. The energy guide chain as claimed in claim 23, wherein the disconnectable connections which connect the plurality of line portions to one another comprise plug-in connections which are pluggable together in a longitudinal direction of the detection line.

25. The energy guide chain as claimed in claim 23, wherein at least one connector is provided for each disconnectable connection between two successive line portions.

26. The energy guide chain as claimed in claim 25, wherein the at least one connector is mechanically held at the neutral axis height of the energy guide chain by a holder on a link or segment and is locked or fixed in a longitudinal direction of the energy guide chain.

27. The energy guide chain as claimed in claim 23, wherein a disconnectable connection for conductively connecting line portions is on at least every second link or segment at least along a part of the length of the energy guide chain.

28. The energy guide chain as claimed in claim 23, wherein the line portions each comprise a pressure hose portion for a pressure medium,
wherein successive line portions are connected by a coupling piece which has a duct for the pressure medium,
wherein a hose nozzle is provided on each of both sides of the coupling piece in a longitudinal direction of the energy guide chain, respectively, and
wherein each hose nozzle provides a disconnectable connection with one of the pressure hose portions, respectively.

29. The energy guide chain as claimed in claim 28, wherein each pressure hose portion comprises a pneumatic pressure hose portion.

30. The energy guide chain as claimed in claim 23, wherein the line portions each comprise an electrical conductor, and wherein each of the disconnectable connections comprises an electrical plug-in connector, respectively.

31. The energy guide chain as claimed in claim 30, wherein each of the plug-in connectors is held at the neutral axis height of the energy guide chain by a holder, wherein the holder has at least one socket configured to fit at least one of the plug-in connectors.

32. The energy guide chain as claimed in claim 23, wherein a tensile strength of each disconnectable connection between two successive line portions is lower than a tensile strength of the two successive line portions, and/or each disconnectable connection between the two successive line portions is non-destructively disconnectable and/or each disconnectable connection between the two successive line portions is disconnectable at a predefined force.

33. The energy guide chain as claimed in claim 23, wherein at least one connector, which is held by a holder on a link or segment, is provided for each disconnectable connection between two successive line portions, and
wherein the holder has a lever projection protruding in a longitudinal direction of the energy guide chain, wherein the lever projection is configured such that, in an event of undesired pivoting of the links or segments, the lever projection interacts with a line portion to undo the disconnectable connection thereof to the next line portion.

34. The energy guide chain as claimed in claim 23, wherein at least one of the line portions of the detection line is disconnectably fastened to at least one of two adjacent links or segments of the energy guide chain.

35. The energy guide chain as claimed in claim 23, wherein the detection line forms a loop, which starts at one end of the energy guide chain and returns to the end of the energy guide chain.

36. The energy guide chain as claimed in claim 35, wherein the energy guide chain comprises links with an accommodation space for accommodating the one or more guided lines, wherein the links comprise side plates which are swivelably connected to one another in a longitudinal direction of the energy guide chain, wherein the detection line is arranged in the accommodation space.

37. The energy guide chain as claimed in claim 36, wherein the side plates are swivelably connected to one another by socket-and-pin connection in the longitudinal direction of the energy guide chain.

38. A kit for retrofitting an energy guide chain with a detection line to detect a malfunction of the energy guide chain, comprising:
a plurality of individual line portions which are conductively connectable to one another by disconnectable connections to form a detection line, the detection line operable such that a malfunction of the energy guide chain leads to at least one of the disconnectable connections being undone in conduction-interrupting manner and a resultant interruption in conduction is detectable with a detector;
connectors for creating the disconnectable connections between the line portions; and
holders to arrange the detection line at a neutral axis height of the energy guide chain along at least part of a length of the energy guide chain.

39. The kit as claimed in claim 38, wherein the holders comprise separating webs which are mountable on links or segments of the energy guide chain.

40. An energy guide chain monitoring system, comprising:
a detection line to detect a malfunction of the energy guide chain, wherein the detection line comprises a plurality of individual line portions which are conductively connected to one another by disconnectable connections, the detection line operable such that a malfunction of the energy guide chain leads to at least one of the disconnectable connections being undone in conduction-interrupting manner and the resultant interruption in conduction being detectable with a detector;
holders to arrange the detection line at a neutral axis height of the energy guide chain along at least part of a length of the energy guide chain;
a source for a detection medium which is conductable by the detection line, wherein the source is connected to the detection line such that the detection medium is feedable into the detection line;
a detector which is connectable to the detection line and operable to detect an interruption in conduction; and
an evaluation unit which is connectable to transfer data to the detector.

41. The monitoring system as claimed in claim 40, wherein:
the source is configured to feed compressed air into the detection line and the detector is embodied as a pressure sensor; or
the source is configured to apply an electrical voltage to the detection line and the detector is configured to monitor the voltage.

42. The monitoring system as claimed in claim 40, wherein the evaluation unit detects a malfunction of the energy guide chain when the detector detects an interruption of the detection line.

43. The monitoring system as claimed in claim 40, wherein the holders comprise separate components which are connectable to links or segments of the energy guide chain.

44. The monitoring system as claimed in claim 40, wherein the disconnectable connections which connect the individual line portions to one another comprise plug-in connections which are disconnectable at a predefined force.
